(19) United States
(12) Patent Application Publication
(10) Pub. No.: US 2013/0255766 A1
(43) Pub. Date: Oct. 3, 2013

(54) CONDUCTIVE PASTE COMPOSITIONS AND SOLAR CELLS USING THE SAME

(71) Applicants: Jung-hwan Shin, Yongin-si (KR); Yong-in Lee, Suwon-si (KR); Jong-woo Lee, Suwon-si (KR); Eun-ah Park, Yongin-si (KR); Ji-ho Uh, Seoul (KR); Cecilia Lee, Suwon-si (KR)

(72) Inventors: Jung-hwan Shin, Yongin-si (KR); Yong-in Lee, Suwon-si (KR); Jong-woo Lee, Suwon-si (KR); Eun-ah Park, Yongin-si (KR); Ji-ho Uh, Seoul (KR); Cecilia Lee, Suwon-si (KR)

(21) Appl. No.: 13/795,521

(22) Filed: Mar. 12, 2013

(30) Foreign Application Priority Data
Mar. 30, 2012 (KR) 10-2012-0033343

(51) Int. Cl. H01L 31/0224

(52) U.S. Cl. CPC H01L 31/022425
USPC 136/256; 252/500; 252/514

(57) ABSTRACT

The present inventive concepts provide a conductive paste composition including conductive particles, a thickening agent, a dispersing agent, a thixotropic agent, an organic solvent, and glass frit, wherein the conductive paste composition has a thixotropic index of about 2 to 7 and a viscosity of about 50,000 to 300,000 cps at a temperature of 25° C.

### CROSS-REFERENCE TO RELATED APPLICATIONS

This application claims the benefit of Korean Patent Application No. 10-2012-0033343, filed on Mar. 30, 2012, in the Korean Intellectual Property Office, the disclosure of which is incorporated herein by reference in its entirety.

### FIELD OF THE INVENTIVE CONCEPT

The inventive concept relates to a solar cell, and more particularly, to a conductive paste composition for forming an electrode having a high aspect ratio and a solar cell using the conductive paste composition.

### BACKGROUND

As the need for development of alternative energy for counteracting exhaustion of fossil fuels and environmental problems increase, development of solar photovoltaic systems representing renewable energy is increasing. In such a solar photovoltaic system, development of a solar cell is a core technology, and the solar cell generates electrical energy by using solar energy and has advantages such as using an inexhaustible energy source and having a longer lifespan. A front electrode of a solar cell may be formed by using a screen printing method, but in such cases, there may be limitations in reducing a line width, and thus a shadowed area may be increased, thereby increasing resistance of the front electrode at least due to a small aspect ratio. Also, since deviations in the shadowed area and the aspect ratio are increased, difficulties may arise in improving efficiency of the solar cell.

### SUMMARY

The inventive concept provides a conductive paste composition for forming a front electrode having a smaller line width and/or an improved aspect ratio.

The inventive concept also provides a solar cell having improved light efficiency by using a conductive paste composition.

According to an aspect of the inventive concept, there is provided a conductive paste composition including conductive particles, a thickening agent, a dispersing agent, a thixotropic agent, an organic solvent, and/or a glass frit, wherein the conductive paste composition has a thixotropic index of about 2 to 7 and a viscosity (at a temperature of 25° C.) of about 50,000 to 300,000 cps.

The conductive particle may include at least one selected from the group consisting of a metal-based material, a metal oxide-based material, and a carbon-based material.

The conductive particle may have a diameter of about 0.05 to 25 μm.

The conductive particle may have a mean diameter (D₅₀) of about 0.5 to 1.5 μm and a maximum diameter (Dₘₐₓ) of about 15 to 25 μm.

The conductive particle may have a weight of about 70 to 95 wt % with respect to the entire weight of the conductive paste composition.

The thickening agent may include at least one selected from the group consisting of a cellulose-based resin, an acryl-based resin, and a polyvinyl-based resin, and the thickening agent has a weight of about 0.1 to 5 wt % with respect to the entire weight of the conductive paste composition.

The dispersing agent may include at least one selected from the group consisting of a copolymer of ethylene oxide and propylene oxide, a nonionic surfactant, and amide, and the dispersing agent has a weight of about 0,1 to 10 wt % with respect to the entire weight of the conductive paste composition.

The thixotropic agent may include at least one selected from the group consisting of caster wax, polyethylene oxide wax, amide wax, linseed oil, and a combination thereof, and the thixotropic agent has a weight of about 0.1 to 10 wt % with respect to the entire weight of the conductive paste composition.

The organic solvent may include at least one selected from the group consisting of terpineol, butyl carbitol, butyl carbitol acetate, butyl cellosolve, butyl cellosolve acetate, texanol, ethylene glycol, aceton, isopropyl alcohol, and ethanol, and the organic solvent has a weight of about 5 to 40 wt % with respect to the entire weight of the conductive paste composition.

According to another aspect of the inventive concept, there is provided a solar cell including conductive particles, a thickening agent, a dispersing agent, a thixotropic agent, an organic solvent, and/or glass frit, wherein the solar cell comprises a front electrode formed of a conductive paste composition having a thixotropic index of about 2 to 7 and a viscosity (at a temperature of 25° C.) of about 50,000 to 300,000 cps.

The front electrode may be formed by using a dispensing nozzle.

The dispensing nozzle may include a needle having an inner diameter of about 50 to 100 μm.

The front electrode may have a line width of about 45 to 65 μm and an aspect ratio of at least about 0.4.

The conductive particle may have a mean diameter (D₅₀) of 0.5 to 1.5 μm and a maximum diameter (Dₘₐₓ) of about 15 to 25 μm.

The conductive paste composition may include conductive particles having a weight of about 70 to 95 wt %, a thickening agent having a weight of about 0.1 to 5 wt %, a dispersing agent having a weight of about 0.1 to 10 wt %, a thixotropic agent having a weight of about 0.1 to 10 wt %, and an organic solvent having a weight of about 5 to 40 wt % with respect to the entire weight of the conductive paste composition.

### BRIEF DESCRIPTION OF THE DRAWINGS

Exemplary embodiments of the inventive concept will be more clearly understood from the following detailed description taken in conjunction with the accompanying drawings in which:

FIG. 1 is a schematic plane view of a silicon solar cell according to an embodiment of the inventive concept;

FIG. 2 is a schematic cross-sectional side view of a silicon solar cell taken along a line II-II′ of FIG. 1;

FIG. 3 is a graph showing sizes and distribution of conductive particles included in a conductive paste composition according to an embodiment of the inventive concept;

FIG. 4 is a graph showing an amount of conductive paste composition discharged from a dispensing nozzle according to a distribution of conductive particles according to an embodiment of the inventive concept;

FIG. 5 is a graph showing an amount of conductive paste composition discharged from a dispensing nozzle according to a viscosity of the conductive paste composition according to an embodiment of the inventive concept;

FIG. 6 is a graph showing an amount of conductive paste composition discharged from a dispensing nozzle according to a viscosity of the conductive paste composition and a variation in a thixotropic index according to an embodiment of the inventive concept;

FIG. 7 is a graph showing an area of a conductive paste composition used in a dispensing method according to a viscosity of the conductive paste composition and a size of a thixotropic index according to an embodiment of the inventive concept; and

FIGS. 8A to 8E are scanning electron microscope (SEM) images of front electrodes formed of conductive paste compositions having different viscosities and thixotropic indexes shown in an oval area of FIG. 7.

### DETAILED DESCRIPTION OF THE EMBODIMENTS

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the concept of the inventive concept to those of ordinary skill in the art. In diagrams, like reference numerals in the drawings denote like elements. In addition, various elements and regions are schematically shown in diagrams. Thus, the inventive concept is not limited to relative sizes and intervals shown in diagrams.

In the present description, terms such as ‘first’, ‘second’, etc. are used to describe various elements. However, it will be obvious that the elements should not be defined by these terms. The terms are used only for distinguishing one element from another element. For example, a first element which could be termed a second element, and similarly, a second element may be termed a first element, without departing from the teaching of the inventive concept.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Expressions such as “at least one of,” when preceding a list of elements, modify the entire list of elements and do not modify the individual elements of the list.

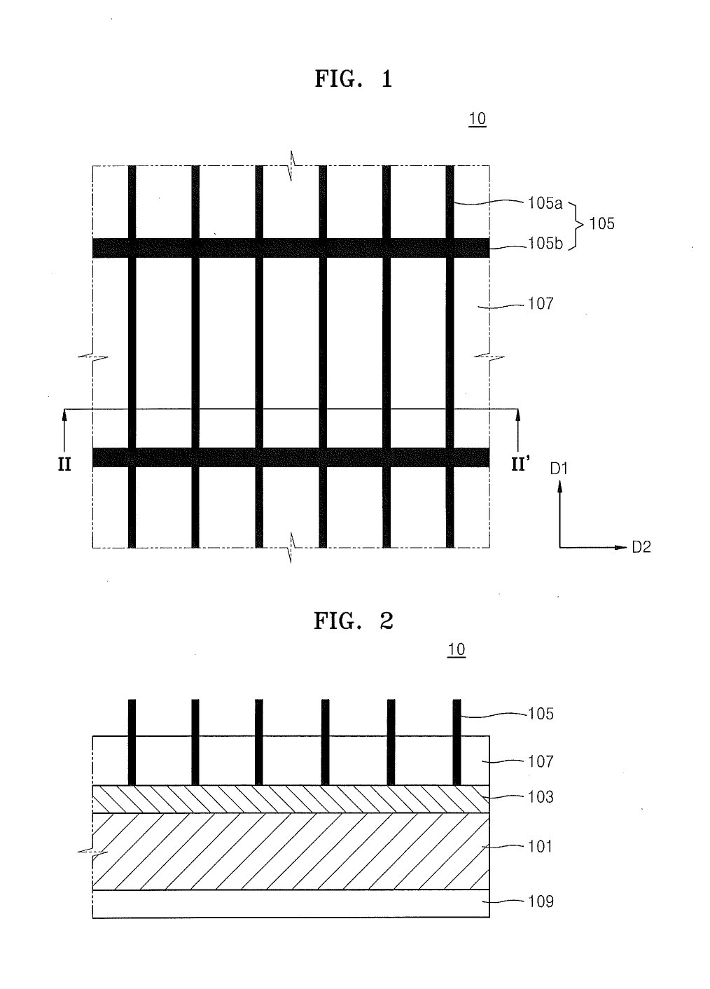

FIG. 1 is a schematic plane view of a solar cell 10 according to an embodiment of the inventive concept. FIG. 2 is a schematic cross-sectional side view of the solar cell 10 taken along a line II-IP of FIG. 1.

Referring to FIGS. 1 and 2, the solar cell 10 includes a first semiconductor layer 101, a second semiconductor layer 103 formed on the first semiconductor layer 101, a front electrode 105 formed on the second semiconductor layer 103, and a rear electrode 109 formed at a rear surface of the first semiconductor layer 101.

The first semiconductor layer 101 may be a first conductive type silicon substrate. For example, the first conductive type may be a p-type. The second semiconductor layer 103 may be a second conductive type silicon substrate that is opposite to the first conductive type silicon substrate. For example, the second conductive type may be an n-type.

The first semiconductor layer 101 and the second semiconductor layer 103 having different conductive types together may form a p-n junction structure.

Also, a reflection barrier layer 107 may be formed on the second semiconductor layer 103. The reflection barrier layer 107 may decrease a reflective ability with respect to solar light and may be formed by one selected from the group consisting of plasma-enhanced chemical vapor deposition (PECVD), chemical vapor deposition (CVD), and sputtering.

Also, the front electrode 105 may include a plurality of finger lines 105a formed in a first direction D1 and a plurality of bus bars 105b formed in a second direction D2 that is substantially perpendicular to the first direction D1. The front electrode 105 may be formed on the second semiconductor layer 103 and penetrate the reflection barrier layer 107 to be electrically connected to the second semiconductor layer 103.

The front electrode 105 may be formed by coating a conductive paste composition on the reflection barrier layer 107 according to a predetermined pattern and then performing an annealing process. The front electrode 105 may penetrate the reflection barrier layer 107 through the annealing process to be electrically connected to the second semiconductor layer 103. The conductive paste composition for forming the front electrode 105 may include conductive particles, a thickening agent, a dispersing agent, a thixotropic agent, an organic solvent, and/or glass frit. The conductive paste composition may have a thixotropic index (TI) (TI=(viscosity at 10 rpm)/(viscosity at 100 rpm)) of 2 to 7 and a viscosity of 50,000 to 300,000 cps (measured by using a Brookfield viscometer at 25° C. and 10 rpm).

The conductive particle may include at least one selected from the group consisting of a metallic material, a metallic oxide-based material, and a carbon-based material. The conductive particle may include at least one selected from the group consisting of a metal-based material, a metal oxide-based material, and a carbon-based material. Also, the conductive particle has a diameter of about 0.05 to 25 μm, and a mean diameter (D₅₀) of the conductive particle may be in a range between about 0.5 and 1.5 μm and a maximum diameter (Dₘₐₓ) of the conductive particle may be in a range between about 15 and 25 μm. A weight of the conductive particle may be in a range between about 70 and 95 wt % with respect to the entire weight of the conductive paste composition.

The thickening agent may include at least one selected from the group consisting of a cellulose-based resin, an acryl-based resin, and a polyvinyl-based resin. A weight of the thickening agent may be in a range between about 0.1 and 5 wt % with respect to the entire weight of the conductive paste composition.

The dispersing agent may include at least one selected from the group consisting of a copolymer of ethylene oxide and propylene oxide, a nonionic surfactant, and amide, and a weight of the dispersing agent may be in a range between about 0.1 and 10 wt % with respect to the entire weight of the dispersing agent.

The thixotropic agent may include at least one selected from the group consisting of caster wax, polyethylene oxide wax, linseed oil, and a combination thereof, and a weight of the thixotropic agent may be in a range between about 0.1 and 10 wt % with respect to the entire weight of the tixotropic agent.

The organic solvent may include at least one selected from the group consisting of terpineol, butyl carbitol, butyl carbitol acetate, butyl cellosolve, butyl cellosolve acetate, texanol, ethylene glycol, aceton, isopropyl alcohol, and ethanol, and a weight of the organic solvent may be in a range between 0.1 and 10 wt % with respect to the entire weight of the organic solvent.

If light is incident on the solar cell 10, negatively-charged electrons and positively-charged holes may be generated due to interaction between the light and a material for forming a semiconductor of the solar cell 10.

Electrons move to the front electrode 105 via the second semiconductor layer 103, and holes move to the rear electrode 109 via the first semiconductor layer 101. If the front electrode 105 and the rear electrode 109 are connected to each other via an electrical wire, current flows, and thus power may be supplied.

In order for the electrons generated in the second semiconductor layer 103 to move smoothly to the front electrode 105, there may be a need to increase a line width of the front electrode 105 formed on the second semiconductor layer 103, particularly, of the finger lines 105a. However, if the line width of the front electrode 105 formed on the second semiconductor layer 103 is increased, an amount of light penetrating the second semiconductor layer 103 may be decreased, thereby decreasing efficiency of the solar cell 10. Accordingly, there may be a need to decrease the line width of the front electrode 105 but increase a height of the front electrode 105.

Thus, when the front electrode 105 is formed of the conductive paste composition, for example, by using a dispensing nozzle through a dispensing method, a more narrow line width and a higher aspect ratio may be obtained. An inner diameter of a needle of the dispensing nozzle may be in a range between about 50 and 100 μm, and the front electrode 105 may have a line width of about 45 to 65 μm and an aspect ratio equal to or greater than about 0.4.

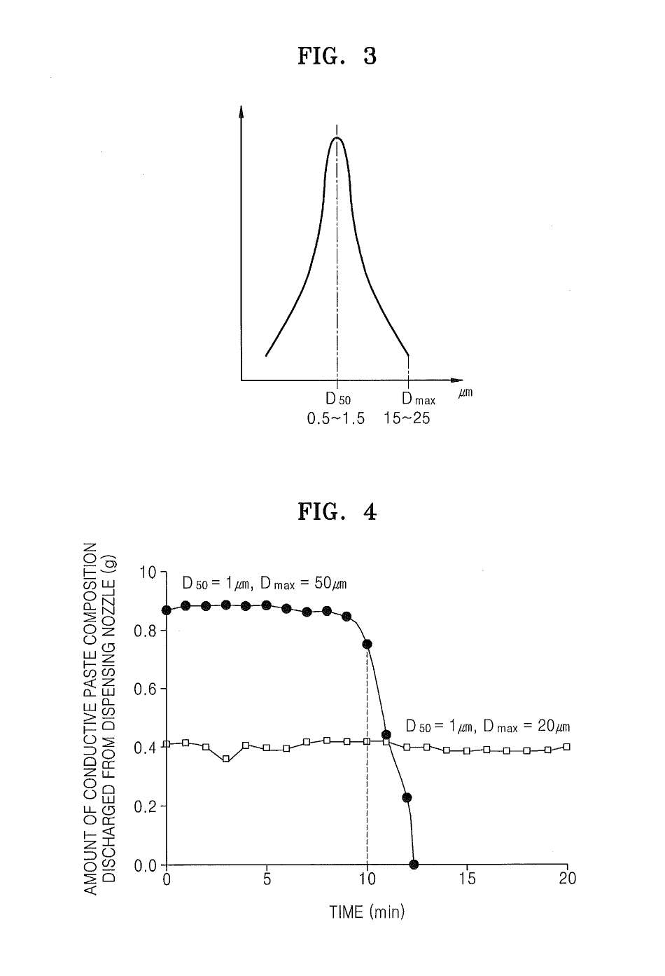

FIG. 3 is a graph showing sizes and distribution of conductive particles included in a conductive paste composition according to an embodiment of the inventive concept.

Unlike a touch type printing method in which pressure is applied on a silicon wafer to form a front electrode as in a screen printing method, a dispensing method is a non-touch type printing method. In the dispensing method, no pressure is applied to a silicon wafer, and thus the silicon wafer may be prevented from being damaged or broken, and an aspect ratio of a front electrode may be improved by decreasing a line width of the front electrode and increasing a height of the front electrode during formation of the front electrode.

However, in the dispensing method, an electrode pattern is formed by using a paste discharged from a nozzle, and thus a conductive paste composition having a composition ratio different from that in a screen printing method is required to prevent the nozzle from becoming clogged.

The conductive paste composition according to the current embodiment may include conductive particles, a thickening agent, a dispersing agent, a thixotropic agent, an organic solvent, and/or glass frit.

Referring to FIG. 3, the conductive paste composition for forming a front electrode of a solar cell by using the dispensing method according to the current embodiment may include conductive particles, and the conductive particle may have a size of about 0.05 to 25 μm, and a mean diameter (D₅₀) of the conductive particle may be in a range between about 0.5 and 1.5 μm and a maximum diameter (Dₘₐₓ) of the conductive particle may be in a range between about 15 and 25 μm.

The conductive particle included in the conductive paste composition according to the current embodiments may be at least one selected from the group consisting of silver (Ag), gold (Au), platinum (Pt), rhodium (Rh), palladium (Pd), nickel (Ni), aluminum (Al), and copper (Cu). Also, the conductive particle may be a metal oxide-based material, which is at least one selected from the group consisting of, for example, indium tin oxide (ITO), fluorine doped tin oxide (FTO), ZnOx, SnO₂, TiO₂, and a combination thereof. Alternatively, the conductive particle may be a carbon-based material, for example, carbon nanotube (CNT) or graphene. However, the inventive concept is not limited thereto, and any suitable conductive material may be used as the conductive particle of the conductive paste composition.

Also, a weight of the conductive particle included in the conductive paste composition may be in a range between about70 and 95 wt % with respect to the entire weight of the conductive paste composition.

The thickening agent included in the conductive paste composition may include at least one selected from the group consisting of a cellulose-based resin, an acryl-based resin, and a polyvinyl-based resin. The cellulose-based resin may be ethyl cellulose, methyl cellulose, nitro cellulose, or hydroxyl ethyl cellulose. Also, the acryl-based resin may be esther acrylate. Also, the polyvinyl-based resin may be polyvinyl alcohol or polyvinyl butyral. However, the inventive concept is not limited thereto.

The content of the thickening agent may be in a range between about 0.1 and 5 wt % with respect to the entire weight of the conductive paste composition.

The dispersing agent included in the conductive paste composition may be a nonionic surfactant. For example, the nonionic surfactant may be primary alcohol ethoxylate, secondary alcohol ethoxylate, lauryl alcohol ethoxylate, lauryl alcohol alkoxilate, or oleyl alcohol ethoxylate. Also, the dispersing agent may be a copolymer of ethyleneoxide and propyleneoxide. Also, the dispersing agent is an amide-type agent and may be diethanolamide, monoethanolamide, or monoethanolamide ethoxylate. However, the inventive concept is not limited thereto.

The content of the dispersing agent may be in a range between about 0.1 and 10 wt % with respect to the entire weight of the conductive paste composition.

The thixotropic agent included in the conductive paste composition may include at least one selected from the group consisting of caster wax, polyethylene oxide wax, amide wax, linseed oil, and a combination thereof.

The content of the thixotropic agent may be in a range between about 0.1 and 10 wt % with respect to the entire weight of the conductive paste compostion.

The organic solvent included in the conductive paste composition may include at least one selected from the group consisting of terpineol, butyl carbitol, butyl carbitol acetate, butyl cellosolve, butyl cellosolve acetate, texanol, ethylene glycol, aceton, isopropyl alcohol and ethanol.

A weight of the organic solvent may be in a range between about 5 and 40 wt % with respect to the entire weight of the conductive paste compostion.

FIG. 4 is a graph showing an amount of conductive paste composition discharged from a dispensing nozzle according to a distribution of conductive particles according to an embodiment of the inventive concept. Here, the amount of conductive paste composition is measured by using the dispensing nozzle having an inner diameter of about 50 jim and a discharging pressure of about 0.8 Mpa.

Referring to FIG. 4, when a front electrode, particularly, a finger line is formed by using a dispensing method, an amount of conductive paste composition discharged varies according to distribution of the conductive particles. In other words, when a mean diameter (D₅₀) of the conductive particle is about 1 μm and a maximum diameter (Dₘₐₓ) of the conductive particle is about 50 μm, the amount of conductive paste composition discharged from the dispensing nozzle is rapidly decreased from a point of time when about 10 minutes have elapsed, and thus the amount of conductive paste composition discharged from the dispensing nozzle is 0 at about 13 minutes, which shows that when the conductive paste composition including a conductive particle having D₅₀ of about 1 μm and Dₘₐₓ of about 50 μm is used, the dispensing nozzle becomes clogged, and thus the conductive paste composition is not appropriate for formation of the finger line.

On the other hand, if a conductive paste composition including a conductive particle having a D₅₀ of about 1 μm and Dₘₐₓ of about 20 μm is used, an amount of the conductive paste composition discharged according to time may be maintained constant and uniform. Thus, sizes and distribution of the conductive particles included in the conductive paste composition may affect the formation of the finger line. According to an embodiment of the inventive concept, when the finger line is formed by using the dispensing method, the conductive particle may have a diameter in a range between about 0.05 and 25 μm and may have D₅₀ of about 0.5 to 1.5 μm and Dₘₐₓ of about 15 to 25 μm.

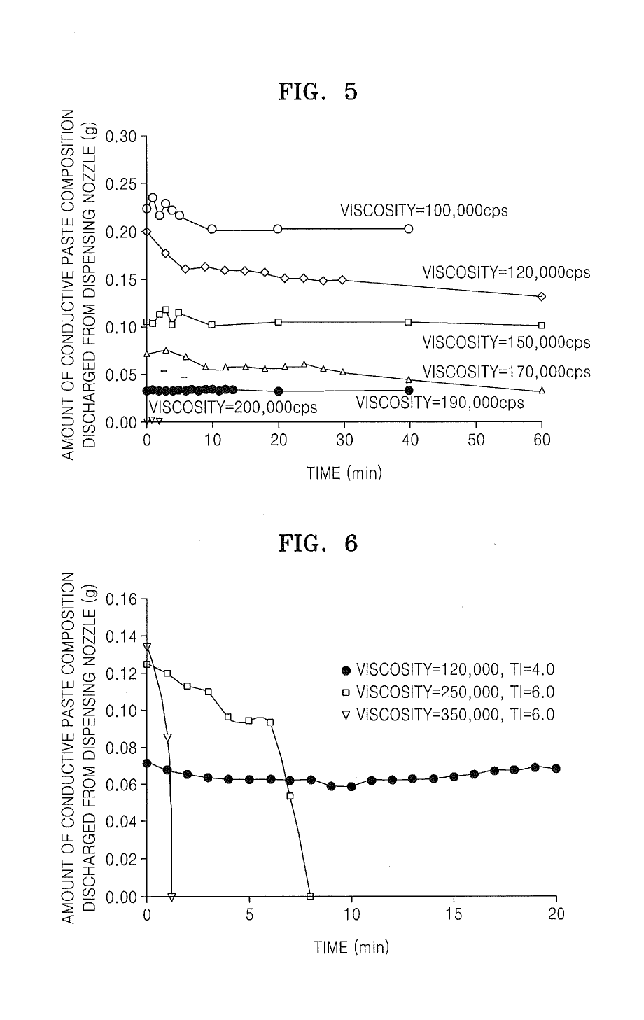

FIG. 5 is a graph showing an amount of conductive paste composition discharged from a dispensing nozzle according to a viscosity of the conductive paste composition according to an embodiment of the inventive concept. Here, the amount of conductive paste composition is measured by using the dispensing nozzle having an inner diameter of about 50 μm and a discharging pressure of about 0.8 Mpa.

FIG. 5 shows the amount of conductive paste composition discharged according to a viscosity of the conductive paste composition measured by using a Brookfield viscometer at 25° C. and 10 rpm.

As the viscosity of the conductive paste composition is increased, the amount of conductive paste composition discharged from the dispensing nozzle is gradually decreased. When the viscosity is 200,000 cps, the conductive paste composition is not discharged from the dispensing nozzle.

Accordingly, in order to secure the conductive paste composition discharged in an amount equal to or more than about 0.1 g/min, the conductive paste composition having a viscosity equal to or less than about 150,000 cps at 25° C. and 10 rpm is used.

FIG. 6 is a graph showing an amount of conductive paste composition discharged from a dispensing nozzle according to a viscosity of the conductive paste composition and a variation in a thixotropic index according to an embodiment of the inventive concept. The conductive paste composition according to the current embodiment may form a front electrode by using the dispensing nozzle including a needle having an inner diameter of about 50 to 100 μm. Here, the amount of conductive paste composition is measured by using the dispensing nozzle having an inner diameter of about 50 μm and discharging pressure of about 0.8 Mpa.

The viscosity of the conductive paste composition is measured by using a Brookfield viscometer at 25° C. and 10 rpm. The thixotropic index (TI) (TI=(viscosity at 10 rpm)/(viscosity at 100 rpm)) of the conductive paste composition is measured by using the Brookfield viscometer at a temperature of 25° C.

The thixotropic index shows a variation in a viscosity according to a shear rate. As the thixotropic index is increased, the conductive paste composition may have a high aspect ratio after the conductive paste composition is discharged from the dispensing nozzle. However, as time passes, the viscosity of the conductive paste composition inside the dispensing nozzle may be gradually decreased, and thus, the amount of conductive paste composition discharged from the dispensing nozzle may be decreased, and consequently, the dispensing nozzle may become clogged by the conductive paste composition.

If the conductive paste composition having a low thixotropic index is used, the dispensing nozzle may be prevented from becoming clogged, but a desired aspect ratio may not be obtained from the discharged conductive paste composition.

Referring to FIG. 6, if the conductive paste composition having a viscosity of 120,000 cps and a thixotropic index of 4.0 is used, the amount of conductive paste composition discharged according to a dispensing time is uniform. However, if the conductive paste composition having a viscosity of 250,000 or 350,000 cps and a thixotropic index of 6.0 is used, the amount of conductive paste composition discharged according to the dispensing time may be rapidly decreased, and thus, the dispensing nozzle becomes clogged.

Accordingly, in order to minimize a reduction in an area of a semiconductor layer generating charges and holes due to incident light and improve movement of the charges and the holes, there is a need to reduce a line width and an aspect ratio of the front electrode, and for this, the viscosity and the thixotropic index of the conductive paste composition should be considered. However, if the viscosity and the thixotropic index of the conductive paste composition are determined only in consideration of efficiency of a solar cell, durability and uniformity of the amount of conductive paste composition discharged may not be secured, thereby decreasing productivity of the solar cell.

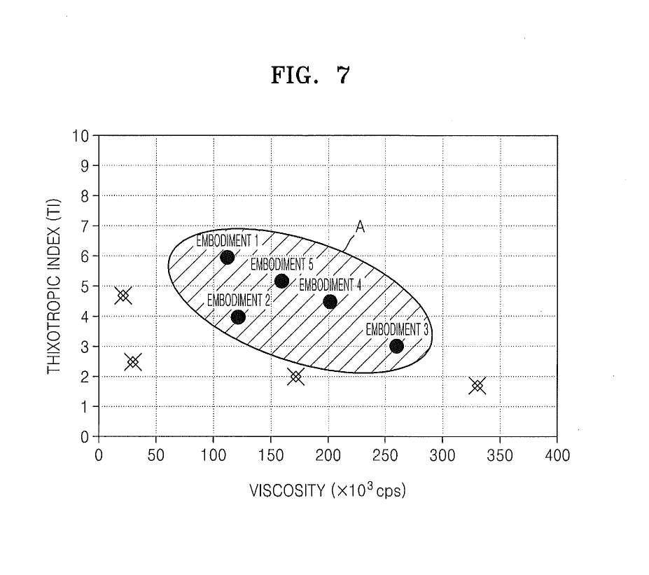

FIG. 7 is a graph showing an area of a conductive paste composition used in a dispensing method according to a viscosity of the conductive paste composition and a size of a thixotropic index according to an embodiment of the inventive concept. A front electrode may be formed of the conductive paste composition by using a dispensing nozzle including a needle having an inner diameter of about 50 to 100 μm. Here, suitability of the conductive paste composition is measured by using a dispensing nozzle including a needle having an inner diameter of about 50 μm and a discharging pressure of about 0.8 Mpa. The viscosity (10 rpm) and the thixotropic index (TI=(viscosity at 10 rpm)/(viscosity at 100 rpm)) of the conductive paste composition are measured by using a Brookfield viscometer at 25° C. and 10 rpm.

Regarding suitability of the conductive paste composition, a case where the conductive paste composition is not discharged from the dispensing nozzle, a case where the conductive paste composition is not discharged because the dispensing nozzle becomes clogged after a predetermined time has elapsed since the discharging of the conductive paste composition, and a case where an aspect ratio of the front electrode does not exceed 0.3 are regarded as inappropriate cases, and thus, these cases are excluded from an appropriate range of a viscosity and a thixotropic index.

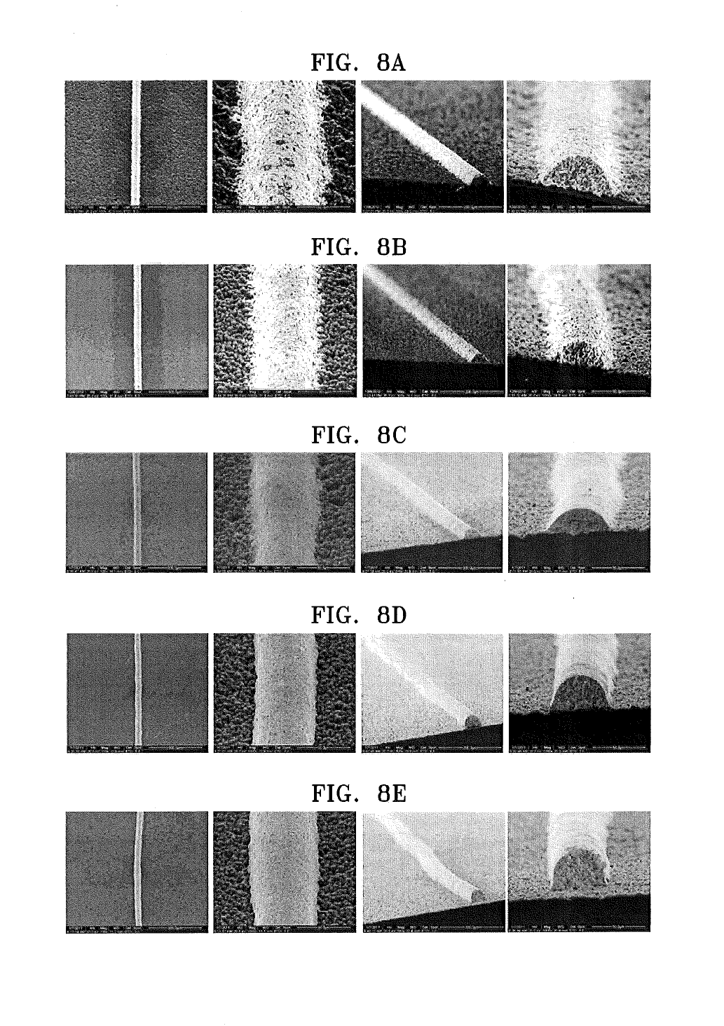

Referring to FIG. 7, the conductive paste composition of some embodiments may have a viscosity and a thixotropic index corresponding to an oval area A. In other words, when the front electrode is formed through a dispensing method by using a conductive paste corresponding to the oval area A, the viscosity may be in a range between about 50,000 and about 300,000 cps, and the thixotropic index may be in a range between about 2 and about 7. As the viscosity of the conductive paste composition is decreased, the conductive paste composition having a thixotropic index that is higher than that of a case where the conductive paste composition has a high viscosity may be used. Also, as the viscosity of the conductive paste composition is increased, the conductive paste composition having a thixotropic index that is lower than that of a case where the conductive paste composition has a low viscosity may be used. In the conductive paste composition of the current embodiment, the viscosity and the thixotropic index tend to be inversely proportional to each other, and the viscosity and the thixotropic index corresponding to the oval area A may be selected to form the front electrode, particularly, a finger line. Since the conductive paste composition of the current embodiment has a viscosity and a thixotropic index corresponding to the oval area A, efficiency and productivity of a solar cell may be increased. Hereinafter, front electrodes formed of conductive paste compositions corresponding to Embodiments 1 to 5 shown inside the oval area A will be described with reference to Tables 1 and 2 and FIGS. 8A to 8E.

FIGS. 8A to 8E are scanning electron microscope (SEM) images of front electrodes formed of conductive paste compositions having different viscosities and thixotropic indexes shown in the oval area A of FIG. 7. Here, the front electrodes are formed by using a dispensing nozzle including a needle having an inner diameter of about 50 μm and a discharging pressure of about 0.8 Mpa. Also, the viscosities and the thixotropic indexes (TI) (TI=(viscosity at 10 rpm)/(viscosity at 100 rpm)) are measured by using a Brookfield viscometer at 25° C. and 10 rpm.

FIG. 8A shows the front electrode formed of the conductive paste composition of Embodiment 1 shown inside the oval area A of FIG. 7. The conductive paste composition of Embodiment 1 (refer to FIG. 7) has a viscosity of 110,000 cps and a thixotropic index of 6.0. In order to form such a conductive paste composition, the conductive paste composition may include conductive particles of about 80 wt %, a thickening agent of about 1 wt %, a thixotropic agent of about 1.7 wt %, an organic solvent of about 15 wt %, and glass frit of about 2 wt %.

The front electrode of FIG. 8A is formed by coating the conductive paste composition by using a dispensing nozzle including a needle having an inner diameter of about 50 μm and a discharging pressure of about 0.8 Mpa, drying, performing burning-out, and performing a calcination process. The front electrode has a line width of about 60±2 μm and an aspect ratio of about 0.5±0.01.

Table 1 shows weights of materials for forming the conductive paste compositions of Embodiments 1 to 5 shown inside the oval area A of FIG. 7. Table 2 shows line widths and aspect ratios of the front electrodes of FIG. 8A to 8E formed of the conductive paste compositions of Embodiments 1 to 5 shown in Table 1. Embodiments 1 to 5 of Table 2 respectively correspond to FIGS. 8A to 8E.

TABLE 1

| | | | conductive | thickening | dispersing | thixotropic | organic | glass | |
|---|---|---|---|---|---|---|---|---|---|
| | viscosity | Thixotropic | particle(Ag) | agent | agent | agent | solvent | frit | |
| | (cps) | index | (wt %) | (wt %) | (wt %) | (wt %) | (wt %) | (wt %) | Remarks |
| Embodiment 1 | 110,000 | 6.0 | 80 | 1 | 0.5 | 1.5 | 15 | 2 | dispensing |
| | | | | | | | | | method |
| Embodiment 2 | 120,000 | 4.0 | 80 | 0.7 | 1.2 | 1.1 | 15 | 2 | dispensing |
| | | | | | | | | | method |
| Embodiment 3 | 260,000 | 3.0 | 80 | 1.3 | 0.9 | 0.8 | 15 | 2 | dispensing |
| | | | | | | | | | method |
| Embodiment 4 | 200,000 | 4.5 | 80 | 0.9 | 1 | 1.1 | 15 | 2 | dispensing |
| | | | | | | | | | method |
| Embodiment 5 | 158,000 | 5.2 | 80 | 0.7 | 1 | 1.3 | 15 | 2 | dispensing |
| | | | | | | | | | method |

TABLE 2

| | Line width | Aspect | |
|---|---|---|---|
| | (μm) | ratio | Remarks |
| Embodiment 1 | 60 ± 2 | 0.5 ± 0.01 | dispensing |
| | | | method |
| Embodiment 2 | 50 ± 2 | 0.5 ± 0.01 | dispensing |
| | | | method |
| Embodiment 3 | 60 ± 3 | 0.5 ± 0.02 | dispensing |
| | | | method |
| Embodiment 4 | 55 ± 3 | 0.55 ± 0.02 | dispensing |
| | | | method |
| Embodiment 5 | 55 ± 3 | 0.58 ± 0.02 | dispensing |
| | | | method |

The front electrodes of FIGS. 8B to 8E may be formed of the conductive paste compositions shown in Table 1 as described above with reference to FIG. 8A, and the line widths and the aspect ratios of the front electrodes of FIGS. 8B to 8E are as shown in Table 2, and thus a detailed description thereof will be omitted here.

Referring to FIGS. 8A to 8E and Table 2, the conductive paste compositions according to the above embodiments of the inventive concept may form a front electrode having a line width of about 45 to 65 μm and an aspect ratio equal to or greater than about 0.4 by using a dispensing method. In other words, the front electrode may be formed to have a reduced line width and a higher aspect ratio by using the conductive paste composition according to the above embodiments of the inventive concept. Also, a desired line width and a desired aspect ratio may be selected by using the conductive paste composition having the thixotropic index and the viscosity corresponding to the oval area A of FIG. 7.

According to one or more embodiments of the inventive concept, a conductive paste composition for forming a front electrode by using a dispensing method can be provided, and thus, a wafer can be prevented from being damaged and broken due to a touch-type printing method. Also, the aspect ratio can be improved by adjusting a line width and a height of the front electrode, and thus, resistance of the front electrode can be decreased, size uniformity of the front electrode can be secured, and efficiency of a solar cell can be increased.

While the inventive concept has been particularly shown and described with reference to exemplary embodiments thereof, it will be understood that various changes in form and details may be made therein without departing from the spirit and scope of the following claims.

What is claimed is:

1. A conductive paste composition comprising conductive particles, a thickening agent, a dispersing agent, a thixotropic agent, an organic solvent, and glass frit, wherein the conductive paste composition has a thixotropic index of about 2 to 7 and a viscosity of about 50,000 to 300,000 cps at a temperature of 25 ° C.

2. The conductive paste composition of claim 1, wherein the conductive particle comprises at least one selected from the group consisting of a metal-based material, a metal oxide-based material, and a carbon-based material.

3. The conductive paste composition of claim 1, wherein the conductive particle has a diameter of about 0.05 to 25 μm.

4. The conductive paste composition of claim 1, wherein the conductive particle has a mean diameter (D₅₀) of about 0.5 to 1.5 μm and a maximum diameter (Dₘₐₓ) of about 15 to 25 μm.

5. The conductive paste composition of claim 1, wherein the conductive particle has a weight of about 70 to 95 wt % with respect to the total weight of the conductive paste composition.

6. The conductive paste composition of claim 1, wherein the thickening agent comprises at least one selected from the group consisting of a cellulose-based resin, an acryl-based resin, and a polyvinyl-based resin, and the thickening agent has a weight of about 0.1 to 5 wt % with respect to the total weight of the conductive paste composition.

7. The conductive paste composition of claim 1, wherein the dispersing agent comprises at least one selected from the group consisting of a copolymer of ethylene oxide and propylene oxide, a nonionic surfactant, and an amide, and the dispersing agent has a weight of about 0.1 to 10 wt % with respect to the total weight of the conductive paste composition.

8. The conductive paste composition of claim 1, wherein the thixotropic agent comprises at least one selected from the group consisting of caster wax, polyethylene oxide wax, amide wax, linseed oil, and a combination thereof, and the thixotropic agent has a weight of about 0.1 to 10 wt % with respect to the total weight of the conductive paste composition.

9. The conductive paste composition of claim 1, wherein the organic solvent comprises at least one selected from the group consisting of terpineol, butyl carbitol, butyl carbitol acetate, butyl cellosolve, butyl cellosolve acetate, texanol, ethylene glycol, aceton, isopropyl alcohol, and ethanol, and the organic solvent has a weight of about 5 to 40 wt % with respect to the total weight of the conductive paste composition.

10. A solar cell comprising conductive particles, a thickening agent, a dispersing agent, a thixotropic agent, an organic solvent, and glass frit, wherein the solar cell comprises a front electrode formed of a conductive paste composition having a thixotropic index of about 2 to 7 and a viscosity of about 50,000 to 300,000 cps at a temperature of 25° C.

11. The solar cell of claim 10, wherein the front electrode is formed by using a dispensing apparatus.

12. The solar cell of claim 11, wherein the dispensing apparatus comprises a needle having an inner diameter of about 50 to 100 μm.

13. The solar cell of claim 10, wherein the front electrode has a line width of about 45 to 65 μm and an aspect ratio of at least about 0.4.

14. The solar cell of claim 10, wherein the conductive particle has a mean diameter (D₅₀) of about 0.5 to 1.5 μm and a maximum diameter (Dₘₐₓ) of about 15 to 25 μm.

15. The solar cell of claim 10, wherein the conductive paste composition comprises conductive particles having a weight of about 70 to 95 wt %, a thickening agent having a weight of about 0.1 to 5 wt %, a dispersing agent having a weight of about 0.1 to 10 wt %, a thixotropic agent having a weight of about 0.1 to 10 wt %, and an organic solvent having a weight of about 5 to 40 wt % with respect to the total weight of the conductive paste composition.

16. A conductive paste composition comprising conductive particles having a weight of about 70 to 95 wt %, a thickening agent having a weight of about 0.1 to 5 wt %, a dispersing agent having a weight of about 0.1 to 10 wt %, a thixotropic agent having a weight of about 0.1 to 10 wt %, and an organic solvent having a weight of about 5 to 40 wt % with respect to the total weight of the conductive paste composition.

17. The conductive paste composition of claim 16, wherein the conductive particle has a mean diameter (D₅₀) of about 0.5 to 1.5 μm and a maximum diameter (Dₘₐₓ) of about 15 to 25 μm.
